(19) United States
(12) Patent Application Publication
(10) Pub. No.: US 2023/0215973 A1
(43) Pub. Date: Jul. 6, 2023

(54) LIGHT EMITTING DEVICE

(71) Applicant: Innolux Corporation, Miaoli County (TW)

(72) Inventors: Hua-Pin Chen, Miaoli County (TW); Ming-Huei Wang, Miaoli County (TW); Shuai Wang, Miaoli County (TW); Yuan-Yi Sung, Miaoli County (TW); Ta-Wei Huang, Miaoli County (TW)

(73) Assignee: Innolux Corporation, Miaoli County (TW)

(21) Appl. No.: 18/073,576

(22) Filed: Dec. 2, 2022

(30) Foreign Application Priority Data
Jan. 4, 2022 (CN) 202210006416.9

(51) Int. Cl. H01L 33/10; H01L 33/50; F21V 8/00

(52) U.S. Cl. CPC H01L 33/10; H01L 33/505; G02B 6/0025; G02B 6/0055

(57) ABSTRACT

A light emitting device, including a substrate, a light guiding element, multiple light sources, and multiple reflecting films. The light guiding element is disposed on the substrate and has multiple through holes. The light sources are disposed on the substrate and are respectively disposed in the through holes. The reflecting films respectively overlap with the light sources.

### CROSS-REFERENCE TO RELATED APPLICATION

This application claims the priority benefit of China application serial no. 202210006416.9, filed on Jan. 4, 2022. The entirety of the above-mentioned patent application is hereby incorporated by reference herein and made a part of this specification.

### BACKGROUND

### Technical Field

The disclosure relates to an electronic device, and more particularly to a light emitting device.

### Description of Related Art

For the light emitting device, how to reduce the overall thickness and maintain the required brightness or brightness uniformity is one of the current issues that researchers intend to solve.

### SUMMARY

The disclosure provides a light emitting device, which can reduce the overall thickness and maintain the required brightness or brightness uniformity.

According to an embodiment of the disclosure, the light emitting device includes a substrate, a light guiding element, multiple light sources, and multiple reflecting films. The light guiding element is disposed on the substrate and has multiple through holes. The light sources are disposed on the substrate and are respectively disposed in the through holes. The reflecting films respectively overlap with the light sources.

In order for the features and advantages of the disclosure to be more comprehensible, the following specific embodiments are described in detail in conjunction with the drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 4 are respectively schematic partial cross-sectional views of a light emitting device according to some embodiments of the disclosure.

### DETAILED DESCRIPTION OF DISCLOSED EMBODIMENTS

Reference will now be made in detail to the exemplary embodiments of the disclosure, and examples of the exemplary embodiments are illustrated in the drawings. Wherever possible, the same reference numerals are used in the drawings and description to refer to the same or similar parts.

Throughout the disclosure and the appended claims, certain terms may be used to refer to specific elements. It should be understood by persons skilled in the art that electronic device manufacturers may refer to the same element by different names. The disclosure does not intend to distinguish between elements with the same function but different names. In the following specification and claims, words such as “containing” and “comprising” are open-ended words, so the words should be interpreted as “including but not limited to . . . ”.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general characteristics of a method, a structure, and/or a material used in a specific embodiment. However, the drawings should not be construed to define or limit the scope or nature covered by the embodiments. For example, the relative sizes, thicknesses, and positions of various film layers, regions, and/or structures may be reduced or enlarged for clarity.

When a structure (or layer, element, base) is described in the disclosure as being located on/above another structure (or layer, element, base), it may mean that the two structures are adjacent and directly connected or it may mean that the two structures are adjacent but not directly connected. Indirect connection means that there is at least one intermediate structure (or intermediate layer, intermediate element, intermediate base, or intermediate spacing) between the two structures, wherein a lower surface of one structure is adjacent to or directly connected to an upper surface of the intermediate structure, and an upper surface of the other structure is adjacent to or directly connected to a lower surface of the intermediate structure. The intermediate structure may be composed of a single-layer or multi-layer physical structure or non-physical structure, which is not limited. In the disclosure, when a certain structure is disposed “on” another structure, it may mean that the certain structure is “directly” on another structure or it may mean that the certain structure is “indirectly” on another structure, that is, at least one structure is also sandwiched between the certain structure and another structure.

The terms “about”, “equal to”, “equivalent” or “same”, “substantially”, or “roughly” are generally interpreted as within 20% of a given value or interpreted as within 10%, 5%, 3%, 2%, 1%, or 0.5% of the given value.

Terms such as “first” and “second” used in the description and claims are used to modify elements and do not imply and represent that the element(s) have any previous ordinal numbers, nor do they represent the order of a certain element and another element or the order of a manufacturing method. The use of the ordinal numbers is only used to clearly distinguish between an element with a certain name and another element with the same name. The claims and description may not use the same terms, whereby a first component in the specification may be a second component in the claims.

Electrical connection or coupling described in the disclosure may refer to direct connection or indirect connection. In the case of direct connection, terminals of elements on two circuits are directly connected or connected to each other by a conductor segment. In the case of indirect connection, there is a switch, a diode, a capacitor, an inductor, a resistor, other suitable elements, or a combination of the above elements between the terminals of the elements on the two circuits, but not limited thereto.

In the disclosure, the measurement manner of thickness, length, and width may be by adopting an optical microscope or a cross-sectional image in an electron microscope, but not limited thereto. In addition, there may be a certain error in any two values or directions used for comparison. Furthermore, the phrases “the given range is from a first value to a second value” and “the given range falls within the range of the first value to the second value” mean that the given range includes the first value, the second value, and other values in between. For example, if a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

It should be noted that in the following embodiments, the features in several different embodiments may be replaced, recombined, and mixed to complete other embodiments without departing from the spirit of the disclosure. As long as the features of the embodiments do not violate the spirit of the invention or conflict with each other, the features may be arbitrarily mixed and matched.

Unless otherwise defined, all terms (including technical and scientific terms) used herein have the same meaning as commonly understood by persons skilled in the art to which the disclosure belongs. It is understood that the terms such as the terms defined in commonly used dictionaries should be interpreted as having meanings consistent with the relevant art and the background or context of the disclosure, and should not be interpreted in an idealized or overly formal manner, unless otherwise defined in the embodiments of the disclosure.

In the disclosure, an electronic device may include a display device, a light emitting device, an antenna device, a sensing device, or a splicing device, but not limited thereto. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light rays, heat, or ultrasonic waves, but not limited thereto. In the disclosure, an electronic element may include a passive element and an active element, such as a capacitor, a resistor, an inductor, a diode, and a transistor. The diode may include a light emitting diode or a photo diode. The light emitting diode may include, for example, an organic light emitting diode (OLED), a mini LED, a micro LED, or a quantum dot LED, but not limited thereto. The splicing device may be, for example, a display splicing device or an antenna splicing device, but not limited thereto. It should be noted that the electronic device may be any combination of the above, but not limited thereto. Hereinafter, the disclosure will be described by using the light emitting device as the electronic device or the splicing device, but the disclosure is not limited thereto.

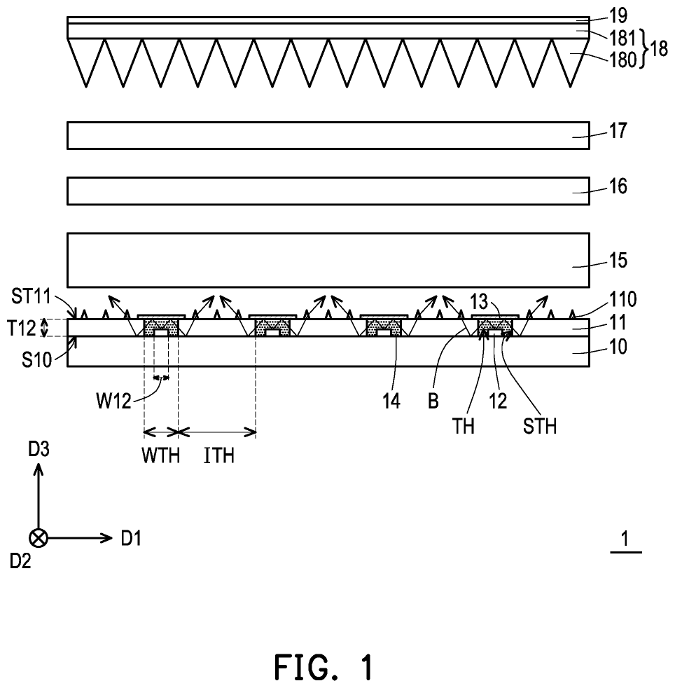

FIG. 1 to FIG. 4 are respectively schematic partial cross-sectional views of a light emitting device according to some embodiments of the disclosure. In FIG. 1 to FIG. 4, the technical solutions provided by different embodiments may be replaced, combined, or mixed for use to form another embodiment without departing from the spirit of the disclosure.

Please refer to FIG. 1. A light emitting device 1 may include a substrate 10, a light guiding element 11, multiple light sources 12, and multiple reflecting films 13. The light guiding element 11 is disposed on the substrate 10 and has multiple through holes TH. The light sources 12 are disposed on the substrate 10 and are respectively disposed in the through holes TH. The reflecting films 13 respectively overlap with the light sources 12. It should be noted that although only one light source 12 is disposed in one through hole TH in the disclosure as an example, the disclosure is not limited thereto. In some embodiments, one through hole 12 may be provided with multiple light sources 12.

In detail, the substrate 10 may include a circuit board or a carrier on which a circuit is formed, but not limited thereto. The circuit board may include a printed circuit board (PCB), a flexible printed circuit board (FPC), etc., but not limited thereto. The material of the carrier may include, glass, plastic, ceramics, quartz, sapphire, or a combination of the above materials, but not limited thereto.

The light guiding element 11 is disposed on the substrate 10. For example, the light guiding element 11 may be attached to the substrate 10 through an adhesive layer (not shown); or the light guiding element 11 may be fixed on the substrate 10 through other mechanical members (not shown), but not limited thereto. The adhesive layer may include an optically clear adhesive (OCA) or an optically clear resin (OCR), but not limited thereto

The light guiding element 11 is adapted to transmit a beam B. For example, the material of the light guiding element 11 may include plastic, such as polyethylene terephthalate (PET), polycarbonate (PC), or polymethyl methacrylate (PMMA), but not limited thereto. In some embodiments, a surface ST11 of the light guiding element 11 (that is, the surface of the light guiding element 11 away from the substrate 10) may be a patterned surface. For example, the surface ST11 of the light guiding element 11 may be formed with multiple microstructures 110, and the beam B transmitted in the light guiding element 11 may be emitted out of the light guiding element 11 from the microstructures 110. In some embodiments, a thickness T12 of the light guiding element 11 may be 0.2 mm to 0.25 mm, that is, 0.2 mm≤T12≤0.25 mm, but not limited thereto. The thickness T12 of the light guiding element 11 may be defined as the shortest distance between the surface ST11 of the light guiding element 11 and a surface S10 of the substrate 10 in a normal direction (for example, a direction D3) of the substrate 10.

In some embodiments, the microstructures 110 may include multiple triangular pyramid-shaped structures or trenches with triangular cross-sections. As shown in FIG. 1, the microstructures 110 may be, for example, arranged in a direction D1 and extend in a direction D2. The direction D1 and the direction D2 intersect and are both perpendicular to the normal direction (for example, the direction D3) of the surface S10 of the substrate 10. In some embodiments, the direction D1 and the direction D2 may be perpendicular to each other, but not limited thereto. In other embodiments, although not shown, the microstructures 110 may include other shapes/types of microstructures. For example, the top-view shape and/or the cross-sectional shape of the microstructure 110 may be a quadrangle, a hexagon, or other polygons, but not limited thereto.

The through holes TH of the light guiding element 11 may be respectively used to accommodate the light sources 12. For example, each through hole TH may accommodate one light source 12, but not limited thereto. In some embodiments, an extending direction of sidewall surfaces STH of the through holes TH may be perpendicular to the surface S10 of the substrate 10, and the through holes TH may be formed through hot stamping to facilitate manufacturing, but not limited thereto. For example, in some embodiments, the extending direction of the sidewall surfaces STH of the through holes TH may form an included angle other than 90 degrees with the surface S10 of the substrate 10. In some embodiments, the through hole TH of the light guiding element 11 may be formed by drilling.

The top-view shape of the through hole TH may be a circle, a quadrangle, or other polygons, which is not limited thereto. In addition, a width WTH of the through hole TH may be greater than a width W12 of the light guiding element 11 and less than a spacing ITH between the through holes TH (that is, W12<WTH<ITH). The width WTH of the through hole TH is the maximum width of the through hole TH in the transection (also referred to as the cross-section) in the direction (for example, the direction D1) parallel to the surface S10 of the substrate 10. The spacing ITH between the through holes TH is the minimum distance between two adjacent through holes TH in the transection in the direction (for example, the direction D1) parallel to the surface S10 of the substrate 10.

At least one light source 12 is disposed in one corresponding through hole TH. The light source 12 may be electrically connected to an external circuit (for example, a power source) through a circuit (not shown) on the substrate 10, so as to provide the beam B. The beam B may be blue light, white light, or other colors/types of light. In some embodiments, the light sources 12 may be arranged in an array to provide an area light source. For example, the light source 12 may include a light emitting diode, such as an organic light emitting diode, a mini light emitting diode, a micro light emitting diode, or a quantum dot light emitting diode, but not limited thereto. In some embodiments, the light source 12 may include a light emitting diode chip. In other embodiments, the light source 12 may include a packaged light emitting diode, that is, the light source 12 may include a light emitting diode die and a protective material covering the light emitting diode die, but not limited thereto.

The reflecting film 13 is disposed above the corresponding light source 12 and overlaps with the corresponding light source 12 in the direction (for example, the direction D3) perpendicular to the surface S10 of the substrate 10. In some embodiments, the reflecting film 13 may fully cover the through hole TH accommodating the light source 12 and partially cover the light guiding element 11, but not limited thereto. The reflecting film 13 may be used to reflect the beam B emitted from the light source 12. For example, the material of the reflecting film 13 may include white paint, white resin, metal, or other suitable reflective materials.

According to different requirements, the light emitting device 1 may further include other elements or film layers. For example, the light emitting device 1 may further include a packaging material 14. The packaging material 14 is disposed in the through hole TH and is located between the light source 12 and the reflecting films 13. For example, the packaging material 14 may cover the corresponding light source 12 and fill the through hole TH, so as to improve the light emitting efficiency. The reflecting film 13 may be disposed on the packaging material 14 and partially cover the light guiding element 11, but not limited thereto. The packaging material 14 may be different from the protective material covering the light emitting diode die. For example, the packaging material 14 may include an ultraviolet curable adhesive, but not limited thereto. The protective material may include a transparent material, a water and oxygen blocking material, other suitable materials, or a combination of the above, but not limited thereto. For example, the protective material may include epoxy, acrylic-based resin, silicone, polyimide polymer, or a combination of the above, but not limited thereto.

In some embodiments, the light emitting device 1 may further include an optical film 15, a light converting layer 16, a diffusion sheet 17, a prism sheet 18, and a matt layer 19, but not limited thereto.

The optical film 15 is disposed above the light guiding element 11 and is, for example, located between the light guiding element 11 and the light converting layer 16. The optical film 15 may, for example, allow a certain beam to pass through and reflect remaining beams. For example, the optical film 15 may allow blue light to pass through and reflect remaining beams (for example, red light, green light, etc.). However, the function of the optical film 15 is not limited thereto.

The light converting layer 16 is disposed between the diffusion sheet 17 and the light guiding element 11. The light converting layer 16 may include a wavelength converting material and/or a light filtering material. For example, the light converting layer 16 may include fluorescence, phosphor, quantum dot (QD), other suitable materials, or a combination of the above, but not limited thereto.

Taking the light source 12 as a blue light emitting diode as an example, the light converting layer 16 may include a wavelength converting material for converting blue light into red light or green light, but not limited thereto. Disposing the optical film 15 between the light guiding element 11 and the light converting layer 16 facilitates the improvement of the light utilization or the brightness. Specifically, the beam B emitted from the light source 12 is transmitted upward to the reflecting film 13 and is then reflected by the reflecting film 13. The beam B reflected by the reflecting film 13 enters the light guiding element 11 from the sidewall surface STH of the through hole TH and at least part of the beam B is transmitted in the light guiding element 11 in a total reflection manner. On the other hand, a part of the beam B transmitted in the light guiding element 11 is emitted out of the light guiding element 11 from the microstructure 110. The optical film 15 disposed between the light guiding element 11 and the light converting layer 16 allows blue light emitted from the light guiding element 11 to pass through, so that the beam B (for example, blue light) from the light guiding element 11 can pass through the optical film 15 and be transmitted to the light converting layer 16. The light converting layer 16 converts blue light into red light or green light, and red light or green light may be transmitted in all directions, wherein red light or green light transmitted toward the light guiding element 11 may be reflected by the optical film 15 again to have the chance to be output from the light emitting device 1.

In other embodiments, the light source 12 may be a white light emitting diode, and the light emitting device 1 may omit the optical film 15 and the light converting layer 16.

The diffusion sheet 17 is disposed between the light guiding element 11 and the prism sheet 18 and is, for example, located between the light converting layer 16 and the prism sheet 18. The diffusion sheet 17 facilitates the improvement of the brightness uniformity.

The prism sheet 18 is disposed above the light guiding element 11. The prism sheet 18 may be used to converge beams to increase the brightness. In some embodiments, the prism sheet 18 may be an inverse prism sheet, that is, a patterned structure 180 in the prism sheet 18 is located on a surface of a base 181 of the prism sheet 18 close to the light guiding element 11. In other embodiments, although not shown, the prism sheet 18 may be a positive prism sheet (the patterned structure 180 in the prism sheet 18 is located on a surface of the base 181 of the prism sheet 18 away from the light guiding element 11).

The matt layer 19 is disposed above the light guiding element 11 and is, for example, located above the base 181 of the prism sheet 18. The matt layer 19 may be used to further improve the brightness uniformity or reduce the visibility of flaws or impurities below. It should be noted that in the disclosure, the matt layer 19 may be formed through patterning the base 181 or disposing another optical film layer with a matt surface on the prism sheet 18.

In the embodiment of FIG. 1, disposing the light guiding element 11 on the substrate 10 and forming the through holes TH accommodating the light sources 12 in the light guiding element 11 facilitate the reduction of the overall thickness of the light emitting device 1. In addition, through the reflecting films 13 above the light source 12 and the patterned surface ST11 (the microstructures 110) of the light guiding element 11, the beam B from the light source 12 may be dispersed to improve the brightness uniformity or facilitate the increase of the spacing between the light sources 12, thereby reducing the number of the light sources 12 or reducing the cost. In addition, disposing the light converting layer 16 above the light guiding element 11 facilitates the formation of white light or the improvement of color purity. Disposing the optical film 15 between the light guiding element 11 and the light converting layer 16 facilitates the improvement of the light utilization or the brightness. Disposing the diffusion sheet 17 above the light guiding element 11 facilitates the improvement of the brightness uniformity. Disposing the prism sheet 18 above the light guiding element 11 may be used to concentrate scattered light upward to increase the brightness of light emitted from the light emitting device 1. Disposing the matt layer 19 above the light guiding element 11 may be used to further improve the brightness uniformity or reduce the visibility of flaws or impurities below.

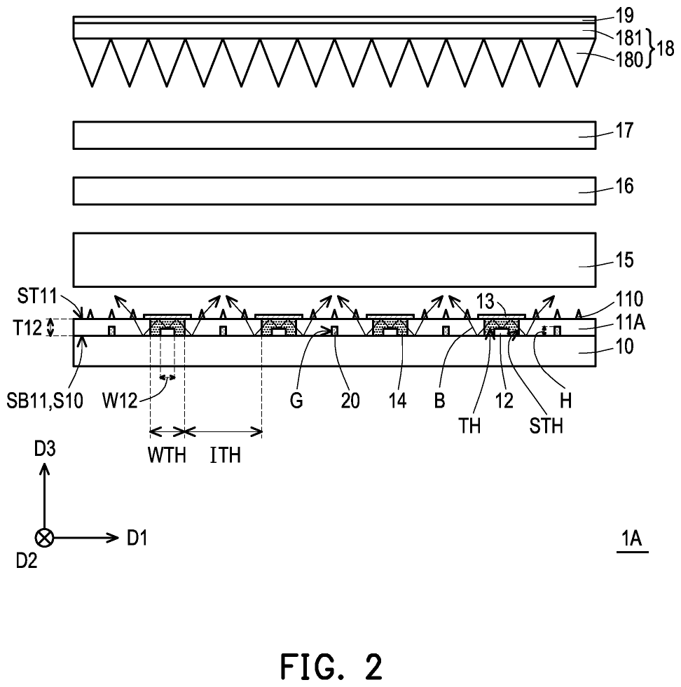

Please refer to FIG. 2. The main differences between a light emitting device 1A and the light emitting device 1 of FIG. 1 are described as follows. The light emitting device 1A further includes multiple retaining wall structures 20. The retaining wall structures 20 are disposed on the substrate 10 and have a maximum height H in the normal direction of the substrate 10. The maximum height H of the retaining wall structure 20 may be less than the thickness T12 of the light guiding element. The light guiding element 11A has multiple grooves G extending from a bottom surface SB11 of the light guiding element 11A to the interior of the light guiding element 11A, and the retaining wall structures 20 are respectively embedded in the grooves G. The light guiding element 11A is fixed on the substrate 10 through the design of the retaining wall structures 20 and the grooves G.

In some embodiments, the material of the retaining wall structure 20 may include a light absorbing material, such as black resin, but not limited thereto. In this way, the retaining wall structure 20 may also be used to shield at least part of the beam B from the adjacent light guiding element 11, which facilitates the implementation of a local dimming function.

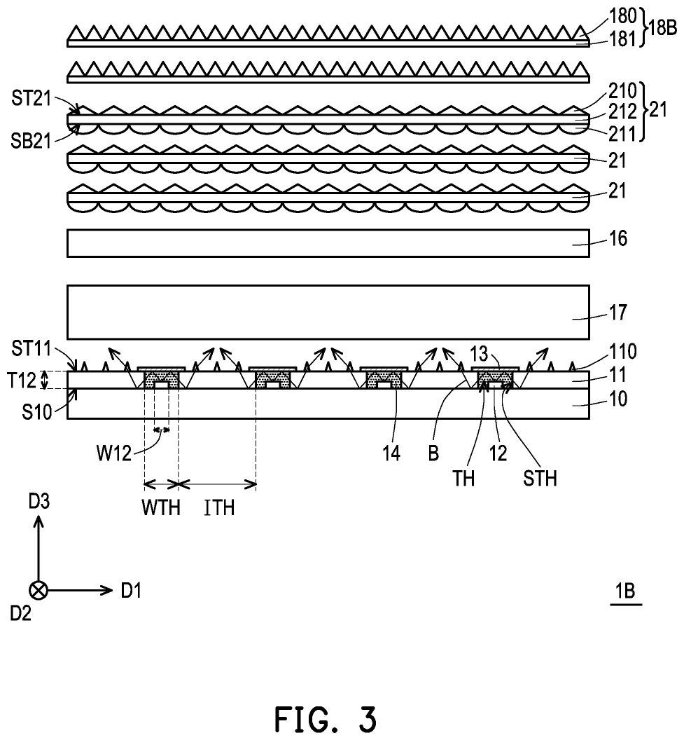

Please refer to FIG. 3. The main differences between a light emitting device 1B and the light emitting device 1 of FIG. 1 are described as follows. In the light emitting device 1B, the light converting layer 16 is disposed between the diffusion sheet 17 and a prism sheet 18B, so that the beam transmitted to the light converting layer 16 is more uniformly distributed. Further, the light emitting device 1B includes one or more (for example, two) prism sheets 18B stacked on the light guiding element 11. The prism sheet 18B may be, for example, a positive prism sheet, that is, the patterned structure 180 in the prism sheet 18B is located on the surface of the base 181 of the prism sheet 18B away from the light guiding element 11.

In some embodiments, the light emitting device 1B may further include one or more (for example, two to five) optical films 21 stacked on the light guiding element 11. The optical films 21 may be, for example, located between the light converting layer 16 and the prism sheet 18B. The optical film 21 may be, for example, used to reduce the visibility of the light sources 12. For example, multiple light concentrating microstructures 210 may be formed on a surface ST21 of a base 212 of the optical film 21, and multiple light dispersing microstructures 211 may be formed on a bottom surface SB21 of the base 212 of the optical film 21. The light concentrating microstructures 210 are, for example, multiple triangular pyramid-shaped microstructures arranged in the direction D1 and extending in the direction D2, but not limited thereto. The light dispersing microstructures 211 are, for example, multiple hemispherical microstructures arranged in the direction D1 and extending in the direction D2, but not limited thereto. The light dispersing microstructures 211 may also be multiple dome-shaped microstructures.

In other embodiments, although not shown, the light emitting device 1B may further include the optical film 15 of FIG. 2, the retaining wall structures 20, or a combination of the above. In other embodiments, although not shown, the light emitting device 1B may omit the light converting layer 16. In other embodiments, although not shown, the prism sheets 18B in FIG. 3 may be replaced by one or more reverse prism sheets (see the prism sheet 18 of FIG. 2).

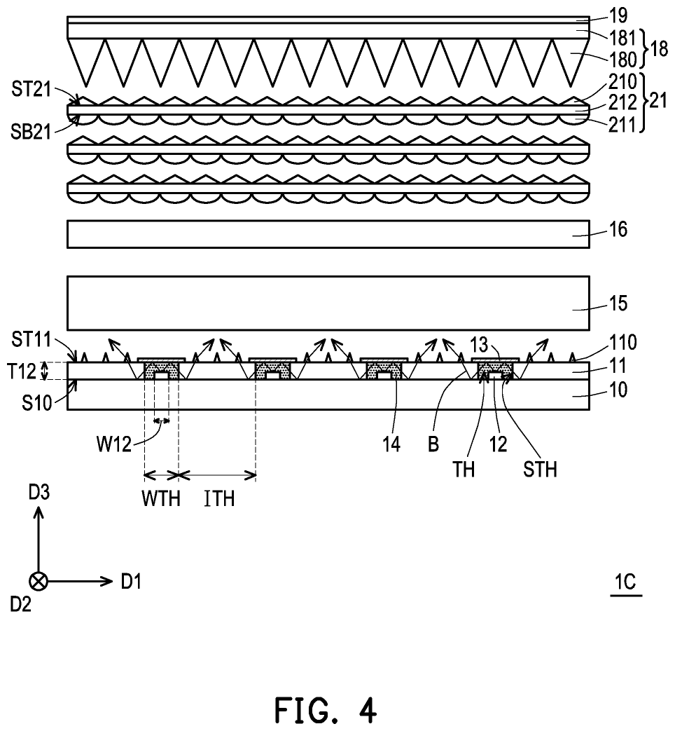

Please refer to FIG. 4. The main differences between a light emitting device 1C and the light emitting device 1 of FIG. 1 are described as follows. In the light emitting device 1C, the diffusion sheet 17 is replaced by multiple optical films 21.

In other embodiments, although not shown, the light emitting device 1B may further include the retaining wall structures 20 of FIG. 2. In other embodiments, although not shown, the light emitting device 1B may omit the light converting layer 16 and the optical film 15. In other embodiments, although not shown, the reverse prism sheet (the prism sheet 18) in FIG. 4 may be replaced by one or more prism sheets 18B in FIG. 3.

In summary, in the embodiments of the disclosure, disposing the light guiding element on the substrate and forming the through holes accommodating the light sources in the light guiding element facilitate the reduction of the overall thickness of the light emitting device. In addition, through the reflecting films 13 above the light source and the patterned surface of the light guiding element, the beam from the light source may be dispersed, which facilitates the increase of the spacing between the light sources, thereby reducing the number of the light sources or reducing the cost. In some embodiments, the brightness uniformity can be achieved or the brightness can be improved through disposing various optical film sheets above the light guiding element.

In addition, the light emitting device of the embodiments of the disclosure may be applied to any electronic device having a panel, such as a mobile device, a tablet, an augmented reality device, a virtual reality device, and a wearable device, but not limited thereto.

Furthermore, structural features or structures in the light emitting device may be observed through manners such as optical microscope (OM) observation.

The above embodiments are only used to illustrate, but not to limit, the technical solutions of the disclosure. Although the disclosure has been described in detail with reference to the above embodiments, persons skilled in the art should understand that the technical solutions described in the above embodiments can still be modified or some or all of the technical features thereof can be equivalently replaced. However, the modifications or replacements do not cause the essence of the corresponding technical solutions to deviate from the scope of the technical solutions of the embodiments of the disclosure.

Although the embodiments of the disclosure and the advantages thereof have been disclosed above, it should be understood that any person skilled in the art can make changes, substitutions, and modifications without departing from the spirit and scope of the disclosure, and the features of the embodiments can be arbitrarily mixed and replaced to form other new embodiments. In addition, the protection scope of the disclosure is not limited to the process, machine, manufacture, material composition, device, method, and steps in the specific embodiments described in the specification. Any person skilled in the art can understand conventional or future-developed processes, machines, manufactures, material compositions, devices, methods, and steps from the content of the disclosure as long as the same can implement substantially the same functions or obtain substantially the same results in the embodiments described herein. Therefore, the protection scope of the disclosure includes the above processes, machines, manufactures, material compositions, devices, methods, and steps. In addition, each claim constitutes a separate embodiment, and the protection scope of the disclosure further includes combinations of the claims and the embodiments. The protection scope of the disclosure should be defined by the appended claims.

What is claimed is:

1. A light emitting device, comprising:
a substrate;
a light guiding element, disposed on the substrate and having a plurality of through holes;
a plurality of light sources, disposed on the substrate and respectively disposed in the through holes; and
a plurality of reflecting films, respectively overlapping with the light sources.

2. The light emitting device according to claim 1, further comprising:
a packaging material, disposed in the through holes and located between the light sources and the reflecting films.

3. The light emitting device according to claim 2, wherein the packaging material is an ultraviolet curable adhesive.

4. The light emitting device according to claim 1, wherein a surface of the light guiding element is a patterned surface.

5. The light emitting device according to claim 1, further comprising:
a prism sheet, disposed above the light guiding element.

6. The light emitting device according to claim 5, wherein the prism sheet is a reverse prism sheet.

7. The light emitting device according to claim 1, further comprising:
a matt layer, disposed on the prism sheet.

8. The light emitting device according to claim 5, further comprising:
a diffusion sheet, disposed between the light guiding element and the prism sheet.

9. The light emitting device according to claim 8, further comprising:
a light converting layer, disposed between the diffusion sheet and the prism sheet.

10. The light emitting device according to claim 9, further comprising:
an optical film, disposed between the light converting layer and the prism sheet, and comprising a plurality of light dispersing microstructures.

11. The light emitting device according to claim 10, wherein the optical film further comprises a base and a plurality of light concentrating microstructures, wherein the light concentrating microstructures are disposed between the base and the prism sheet, and the light dispersing microstructures are disposed between the base and the light converting layer.

12. The light emitting device according to claim 11, wherein the light concentrating microstructures are a plurality of triangular pyramid-shaped microstructures, and the light dispersing microstructures are a plurality of hemispherical microstructures or a plurality of dome-shaped microstructures.

13. The light emitting device according to claim 8, further comprising:
a light converting layer, disposed between the diffusion sheet and the light guiding element.

14. The light emitting device according to claim 13, further comprising:
an optical film, disposed between the light converting layer and the light guiding element, and allowing blue light to pass through and reflecting remaining beams.

15. The light emitting device according to claim 5, further comprising:
a light converting layer, disposed between the light guiding element and the prism sheet.

16. The light emitting device according to claim 15, further comprising:
an optical film, disposed between the light converting layer and the prism sheet, and the optical film includes a plurality of light dispersing microstructures.

17. The light emitting device according to claim 16, wherein the optical film further comprises a base and a plurality of light concentrating microstructures, wherein the light concentrating microstructures are disposed between the base and the prism sheet, and the light dispersing microstructures are disposed between the base and the light converting layer.

18. The light emitting device according to claim 17, wherein the light concentrating microstructures are a plurality of triangular pyramid-shaped microstructures, and the light dispersing microstructures are a plurality of hemispherical microstructures or a plurality of dome-shaped microstructures.

19. The light emitting device according to claim 16, further comprising:
another optical film, disposed between the light converting layer and the light guiding element, and allowing blue light to pass through and reflecting remaining beams.

20. The light emitting device according to claim 1, further comprising:
a plurality of retaining wall structures, disposed on the substrate,
wherein the light guiding element has a plurality of grooves extending from a bottom surface of the light guiding element to an interior of the light guiding element, and the retaining wall structures are respectively embedded in the grooves.
